(19) United States
(12) Patent Application Publication
(10) Pub. No.: US 2002/0052665 A1
(43) Pub. Date: May 2, 2002

(54) Utilizing vacuum tubes in computer audio circuitry

(76) Inventor: Louis I. Memran, Tamarae, FL (US)

Correspondence Address: Donald J. Ersler, 725 Gravens Avenue, Brookfield, WI, 53005, US

(21) Appl. No.: 10/002,382

(22) Filed: Oct. 20, 2001

Related U.S. Application Data
(60) Provisional application No. 60/245,285, filed on Nov. 1, 2000.

(51) Int. Cl. H03G 3/00; G06F 17/00

(52) U.S. Cl. 700/94; 381/61

(57) ABSTRACT

A tube card preferably includes at least one vacuum tube and a DC to DC high voltage converter. The at least one vacuum tube is supplied with high voltage from the DC to DC voltage converter. The tube card may be used as an additional amplification stage for an analog output of a sound card, or as a preamplifier for an analog input of the sound card. A combination tube card includes at least one vacuum tube, the DC to DC high voltage converter, and a sound chip. The sound chip eliminates the need for a stand alone sound card. The at least one vacuum tube is supplied with high voltage from the DC to DC high voltage converter. The combination tube card replaces the need for having separate tube and sound cards.

### CROSS-REFERENCES TO RELATED APPLICATIONS

This is a utility application, taking priority from provisional patent application, serial number 60/245,285 filed on Nov. 1, 2000.

### BACKGROUND OF THE INVENTION 1. Field of the Invention

The present invention relates generally to computer audio circuitry and more specifically to utilizing vacuum tubes in computer audio circuitry for amplification and sound massaging of audio signals inside the computer.

2. Discussion of the Prior Art

Currently, solid state devices (transistors, integrated circuits, diodes, etc.) are used for amplifying audio signals in computer audio circuitry. Transistors are compact, cheap, and reliable. However, transistors do not produce an audio sound which is pleasant to the ears. Coupled with inexpensive digital to analog converters, the sound that transistors produce is hard and edgy. Hard and edgy characteristics do not compliment the sound of low cost speakers used with most computers. Vacuum tubes are used in many expensive audio sound systems, but require large transformers and other ancillary vacuum tubes for operation.

Accordingly, there is a clearly felt need in the art for utilizing vacuum tubes in computer audio circuitry which amplify and smooth the sound of audio signals inside a computer at a reasonable cost.

### DEFINITIONS

A computer is an electronics device that contains at least one microprocessor, sound card circuitry, and at least one storage device such as memory chips, hard disk, or CD-ROM. A sound chip is an electronics device which contains an analog to digital (A/D) and/or digital to analog (D/A) converter and sound signal processing devices such as buffers or amplifiers. An external device may be a preamplifier, power amplifier, sound mixer, amplified speakers, headphone, or any other sound processing device. An audio input device may be a microphone, tape recorder, guitar, CD player, or any audio device which may be recorded by a computer.

### SUMMARY OF THE INVENTION

The present invention provides the utilization of vacuum tubes in computer audio circuitry to replace or modify the sound of input/output stages. A tube card preferably includes at least one vacuum tube, a DC to DC high voltage converter, at least one resistor, and at least one capacitor. The at least one vacuum tube is supplied with high voltage from the DC to DC high voltage converter. The at least one resistor and capacitor are connected or coupled to the at least one vacuum tube. The tube card may be connected to a sound card in two different ways. First, the tube card may be connected in series between an analog output of the sound card and an external device to provide an additional amplification stage or to smooth the analog output from the sound card. Second, the tube card may be inserted in series between a audio input device and an analog input of the sound card to provide a preamplification stage or to smooth the analog input into the sound card.

A combination tube card preferably includes at least one vacuum tube, a DC to DC high voltage converter, a sound chip, at least one resistor, and at least one capacitor. The sound chip includes an analog input, analog output, and digital input/output. The sound chip eliminates the need for a stand alone sound card. The at least one vacuum tube is supplied with high voltage from the DC to DC high voltage converter. The at least one resistor and capacitor are connected to the at least one vacuum tube. The combination tube card may be configured two different ways. First, the combination tube card may be configured to provide an additional amplification stage or to smooth the analog output from the sound chip. Second, the combination tube card may be configured to provide a preamplification stage or to smooth the analog input into the sound card.

Accordingly, it is an object of the present invention to provide the utilization of vacuum tubes in computer audio circuitry to act as an additional amplification stage for an analog output.

It is a further object of the present invention to provide the utilization of vacuum tubes in computer audio circuitry to smooth an analog signal.

Finally, it is another object of the present invention to provide the utilization of vacuum tubes in computer audio circuitry to act as a preamplification stage for an analog input.

These and additional objects, advantages, features and benefits of the present invention will become apparent from the following specification.

### BRIEF DESCRIPTION OF THE DRAWINGS

FIG. 1 is a schematic diagram of a tube card used as an additional amplification stage for an analog output of a sound card in accordance with the present invention.

FIG. 2 is a schematic diagram of a tube card used as a preamplification stage for an analog input of a sound card in accordance with the present invention.

FIG. 3 is a schematic diagram of a combination tube card configured with an additional amplification stage for an analog output of a sound chip in accordance with the present invention.

FIG. 4 is a schematic diagram of a combination tube card used as a preamplification stage for an analog input of a sound card in accordance with the present invention.

### DETAILED DESCRIPTION OF THE PREFERRED EMBODIMENTS

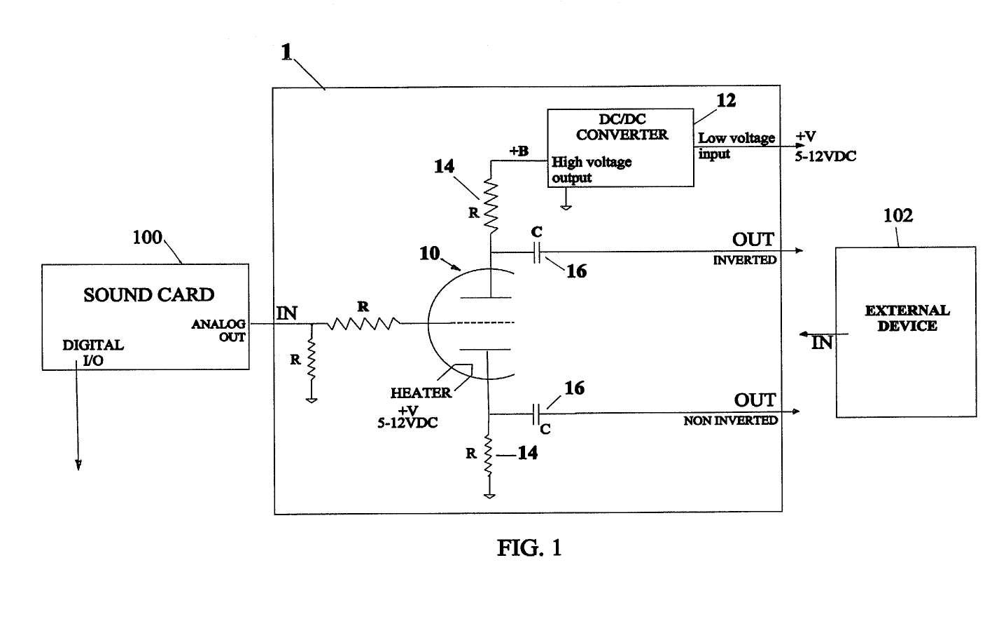

With reference now to the drawings, and particularly to FIG. 1, there is shown a schematic diagram of a tube card 1. The tube card 1 preferably includes at least one vacuum tube 10, a DC to DC high voltage converter 12, at least one resistor 14, and at least one capacitor 16. The at least one vacuum tube 10 is supplied with high voltage from the DC to DC high voltage converter 12. The vacuum tube 10 has an input, an inverted output, and a non-inverted output. The value of high voltage ranges from 50 to 1,000 volts DC. The computer power supply is used to supply the heater of the at least one vacuum tube 10 with electrical power. It is preferable to use a 12AX7, 12AT7, or ECCA83 vacuum tube, but other types of vacuum tubes may also be used. The at least one resistor and capacitor are connected to the at least one vacuum tube 10.

The tube card 1 may be connected to a sound card 100 in two different ways. The tube card 1 may be connected in series between an analog output of the sound card 100 and an external device 102 to provide an additional amplification stage or to smooth the analog output from the sound card 100. The external device 102 may be connected to the inverted or noninverted outputs of the vacuum tube 10. The sound card 100 has a digital input/output connected to the motherboard of the computer.

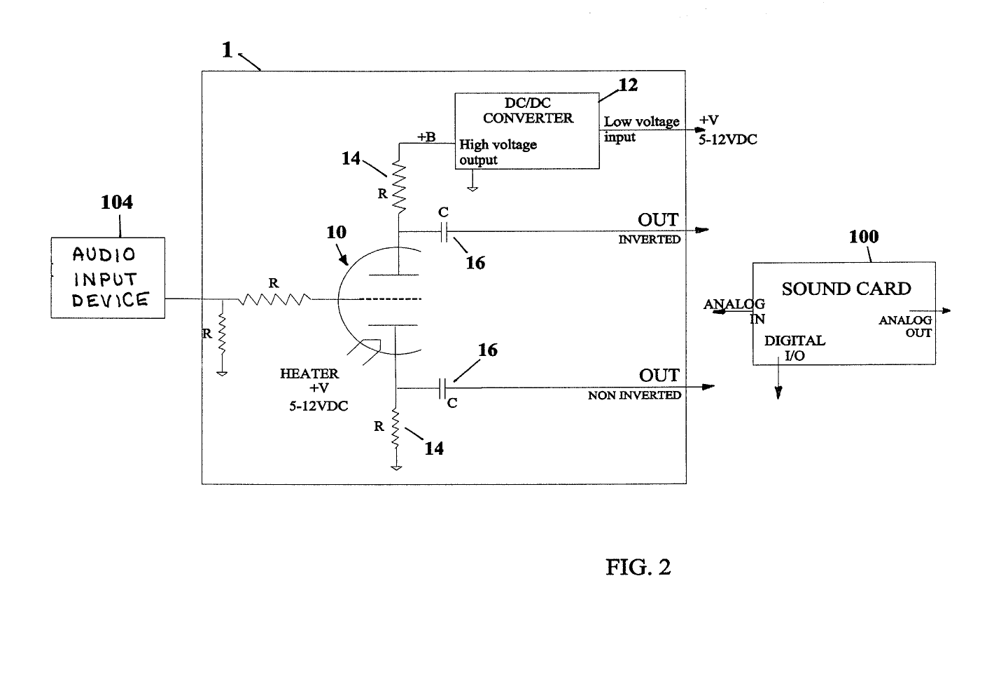

With reference to FIG. 2, the tube card 1 may be inserted in series between an audio input device 104 and an analog input of the sound card 100 to provide a preamplification stage or to smooth the analog input into the sound card 100. An analog input of the sound card 100 may be connected to the inverted or noninverted outputs of the vacuum tube 10. One tube circuit is shown on the tube card 1, but two or more tube circuits could be placed on each tube card 1 to accommodate stereo, surround audio, or to have two sets of analog input and output lines. One vacuum tube 10 is shown for each analog input and output line, but more than one vacuum tube could be used. The inverted and noninverted output lines of the vacuum tube 10 are considered one analog output line.

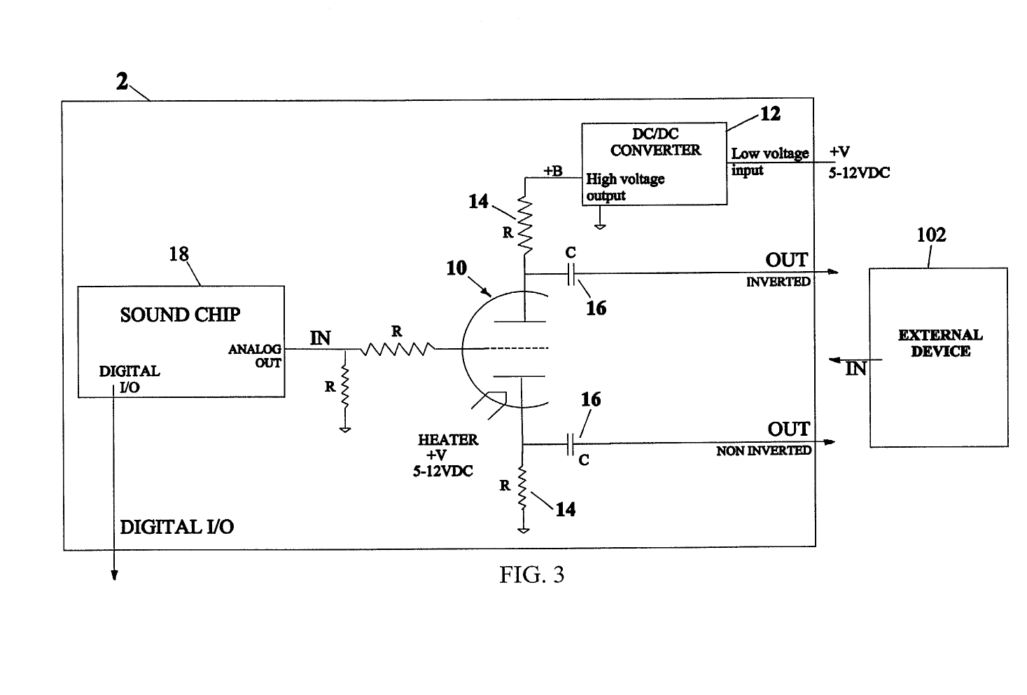

With reference to FIG. 3, a combination tube card 2 preferably includes at least one vacuum tube 10, the DC to DC high voltage converter 12, a sound chip 18, at least one resistor 14, and at least one capacitor 16. The sound chip 18 includes an analog input, analog output, and digital input/output. The digital input/output of the sound chip 18 is connected to the motherboard of the computer. The sound chip 18 eliminates the need for a stand alone sound card 100. The at least one vacuum tube 10 is supplied with high voltage from the DC to DC high voltage converter 12. The at least one resistor and capacitor are connected to the at least one vacuum tube 10.

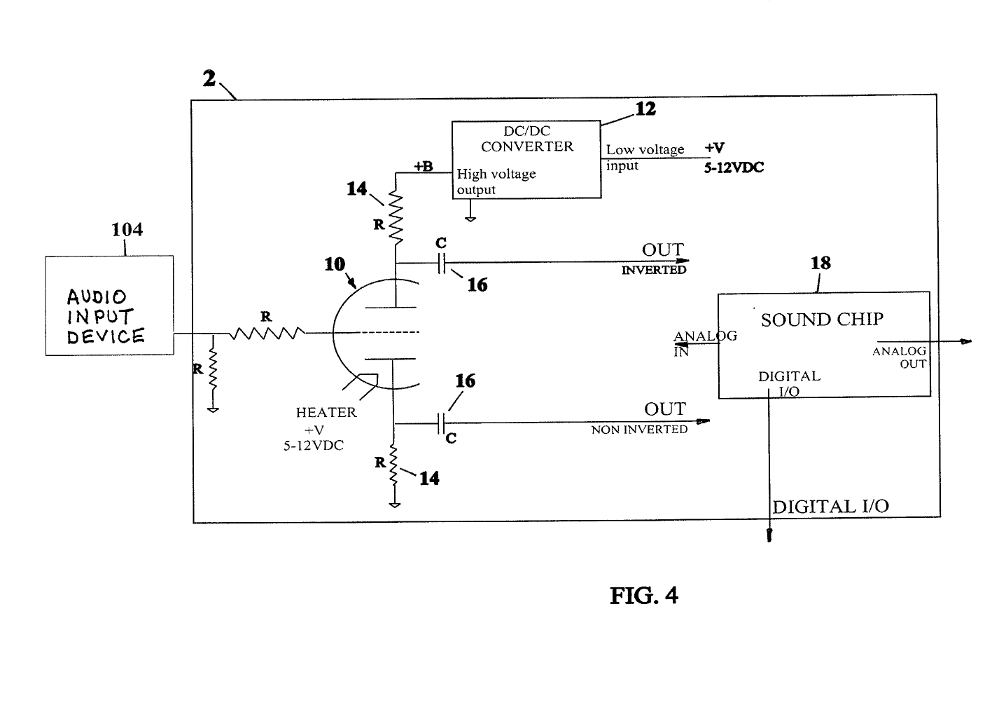

The combination tube card 2 may be configured two different ways. The combination tube card 2 may be configured to provide an additional amplification stage or to smooth the analog output to an external device 102 from the sound chip 18. The external device 102 may be connected to the inverted or noninverted outputs of the vacuum tube 10. With reference to FIG. 4, the combination card 2 may be configured to provide a preamplification stage or to smooth the electrical signal from an audio input device 104 into an analog input of the sound chip 18. The analog input of the sound card 100 may be connected to the inverted or noninverted outputs of the vacuum tube 10. One tube circuit is shown on the combination tube card 2, but two or more tube circuits could be placed on combination each tube card 2 to accommodate stereo, surround audio, or to have two sets of analog input and output lines. One vacuum tube 10 is shown for each analog input and output line, but more than one vacuum tube could be used. The inverted and noninverted output lines of the vacuum tube 10 are considered one analog output line.

While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

I claim:

1. A tube card for use with computer audio circuitry comprising:
at least one vacuum tube, each said vacuum tube having an input and an output;
a DC to DC voltage converter supplying high voltage to said vacuum tube; and
an analog output signal from a sound card being input into said at least one vacuum tube, said output of said at least one vacuum tube being connected to an external device.

2. The tube card for use with computer audio circuitry of claim 1, wherein:
a heater of each said at least one vacuum tube being supplied with electrical power from a computer power supply.

3. A tube card for use with computer audio circuitry comprising:
at least one vacuum tube, each said vacuum tube having an input and an output;
a DC to DC voltage converter supplying high voltage to said vacuum tube; and
an analog input of a sound card being coupled to an audio input device through said at least one vacuum tube, an electrical signal from said audio input device being preamplified by said at least one vacuum tube.

4. The tube card for use with computer audio circuitry of claim 3, wherein:
a heater of each said at least one vacuum tube being supplied with electrical power from a computer power supply.

5. A combination tube card for use with computer audio circuitry comprising:
at least one vacuum tube, each said vacuum tube having an input and an output;
a DC to DC voltage converter supplying high voltage to said vacuum tube; and
a sound chip having an analog output, said analog output being connected to an input of at least one vacuum tube, said output of said at least one vacuum tube being connected to an external device.

6. The combination tube card for use with computer audio circuitry of claim 5, wherein:
said sound chip having a digital input/output, said digital input/output being connected to a motherboard of a computer.

7. The combination tube card for use with computer audio circuitry of claim 5, wherein:
a heater of each said at least one vacuum tube being supplied with electrical power from a computer power supply.

8. A tube card for use with computer audio circuitry comprising:
at least one vacuum tube, each said vacuum tube having an input and an output;
a DC/DC voltage converter supplying high voltage to said vacuum tube; and
a sound chip having an analog input, said analog input being coupled to an audio input device through at least one vacuum tube, an electrical signal from said audio input device being preamplified by said at least one vacuum tube.

9. The combination tube card for use with computer audio circuitry of claim 8, wherein:
said sound chip having a digital input/output, said digital input/output being connected to a motherboard of a computer.

10. The combination tube card for use with computer audio circuitry of claim 8, wherein:
a heater of each said at least one vacuum tube being supplied with electrical power from a computer power supply.
